(19) United States
(12) Patent Application Publication
(10) Pub. No.: US 2026/0092972 A1
(43) Pub. Date: Apr. 2, 2026

(54) SYSTEM AND METHOD FOR ESTIMATING BATTERY STATE-OF-CHARGE (SOC) VIA HYBRID ALGORITHM APPROACH

(71) Applicant: Apple Inc., Cupertino, CA (US)

(72) Inventor: Soham Banerjee, San Jose, CA (US)

(21) Appl. No.: 18/900,211

(22) Filed: Sep. 27, 2024

(51) Int. Cl. G01R 31/367; G01R 31/36; G01R 31/3842

(52) U.S. Cl. CPC G01R 31/367; G01R 31/3648; G01R 31/3842

(57) ABSTRACT

One or more tangible, non-transitory, computer-readable media storing instructions thereon that, when executed by processing circuitry, are configured to cause the processing circuitry to perform various functions. The functions include determining a state-of-charge (SOC) of a battery during a first interval of time via a voltage look-up algorithm, transitioning from the voltage look-up algorithm to a Coulomb counting algorithm based on battery characteristic data satisfying transition criteria, and determining the SOC of the battery during a second interval of time after the first interval of time via the Coulomb counting algorithm.

### BACKGROUND

The present disclosure relates generally to a battery, such as a secondary or rechargeable battery (e.g., lithium-ion battery), and more specifically to estimating a state-of-charge (SOC) of the battery via a hybrid algorithm approach.

Certain batteries configured to power certain loads (e.g., certain electronic devices) may include one or more application-specific integrated circuits (ASICs) configured to determine a state-of-charge (SOC) of the battery. While ASICs may be adequate for determining the SOC, ASICs may require a relatively large power draw from the battery to operate, causing the battery to discharge at an undesirably high rate. For this reason, certain such batteries may require frequent charging, negatively affecting an experience of a user of the load. One solution to these problems has been to increase a size of the battery, thereby increasing a capacity of the battery, which at least partially reduces a necessary charging frequency despite the relatively high discharge rate associated with batteries employing one or more ASICs to determine the SOC. However, certain loads are relatively small by design and/or otherwise incompatible (e.g., mechanically incompatible, electrically incompatible, functionally incompatible, aesthetically incompatible, etc.) with relatively large batteries. In other words, a form factor of certain loads is not suitable for relatively large batteries employing one or more ASICs. Hardware gas gauge mechanisms, which also have been used to determine the SOC of certain batteries, suffer similar problems in terms of size and power draw. Accordingly, ASICs and/or hardware gas gauge mechanisms may not be practical for use in certain batteries powering certain loads (e.g., relatively small loads).

Certain relatively small batteries employed in certain relatively small loads may include other mechanisms for determining the SOC. However, these mechanisms may be susceptible to determining an inaccurate SOC at various intervals, such as intervals where various conditions (e.g., temperature, voltage, etc.) are unstable or otherwise in flux, which negatively affects an experience of a user with the load. For example, the battery may reach full discharge more quickly than the user expects, causing the load to power off before the user has an opportunity to charge the battery. Additionally or alternatively, if other aspects of the battery, the load, or both rely on an accurate determination of the SOC for making one or more operating decisions (e.g., when to enter or recommend entering a power saving mode, when to close or recommend closing certain applications, etc.), an inaccurate SOC may negatively affect such operating decision(s). Accordingly, it is now recognized that improved systems and methods for determining an SOC of a battery, such as an SOC of a relatively small battery powering a relatively small load, are desired.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In an embodiment, one or more tangible, non-transitory, computer-readable media storing instructions thereon that, when executed by processing circuitry, are configured to cause the processing circuitry to perform various functions. The functions include determining a state-of-charge (SOC) of a battery during a first interval of time via a voltage look-up algorithm, transitioning from the voltage look-up algorithm to a Coulomb counting algorithm based on battery characteristic data satisfying transition criteria, and determining the SOC of the battery during a second interval of time after the first interval of time via the Coulomb counting algorithm.

In another embodiment, a battery includes a battery management unit (BMU). The BMU is configured to determine a state-of-charge (SOC) of the battery during a first interval of time via a voltage look-up algorithm, transition from the voltage look-up algorithm to a Coulomb counting algorithm based on battery characteristic data satisfying transition criteria, and determine the SOC of the battery during a second interval of time after the first interval of time via the Coulomb counting algorithm.

In another embodiment, a method includes determining a state-of-charge (SOC) of a battery via a hybrid algorithm comprising a voltage look-up algorithm component and a Coulomb counting algorithm component, transitioning from the voltage look-up algorithm component to the Coulomb counting algorithm component based on battery characteristic data satisfying transition criteria, transitioning from the Coulomb counting algorithm component to the voltage look-up algorithm component based on additional battery characteristic data satisfying additional transition criteria.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a schematic illustration of an electrical system including a device (e.g., an audio device, such as wireless earbuds), a case for holding the device, and an additional device (e.g., a mobile device, such as a smartphone), according to embodiments of the present disclosure;

FIG. 3 is a schematic illustration of a battery employed in the device of FIG. 2, according to embodiments of the present disclosure;

FIG. 4 is a high-level process flow diagram illustrating a method of determining a state-of-charge of the battery of FIG. 3, in which a hybrid algorithm approach including a voltage look-up algorithm and a Coulomb counting algorithm are employed, according to embodiments of the present disclosure;

FIG. 5A is a first portion of a detailed process flow diagram illustrating hybrid algorithm logic for determining a state-of-charge of the battery of FIG. 3, according to embodiments of the present disclosure;

FIG. 5B is a second portion of a detailed process flow diagram illustrating a hybrid algorithm logic for determining a state-of-charge of the battery of FIG. 3 (e.g., continuing from the first portion in FIG. 5A), according to embodiments of the present disclosure;

FIG. 6 is a process flow diagram illustrating a filter engage implementation of a hybrid algorithm approach for determining a state-of-charge of the battery of FIG. 3, according to embodiments of the present disclosure; and

FIG. 7 is a process flow diagram illustrating a filter out transition implementation of a hybrid algorithm approach for determining a state-of-charge of the battery of FIG. 3, according to embodiments of the present disclosure; and

FIG. 8 is a process flow diagram illustrating a filter disengage implementation of a hybrid algorithm approach for determining a state-of-charge of the battery of FIG. 3, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on).

This disclosure is directed to a battery, such as a secondary or rechargeable battery (e.g., lithium-ion battery). More specifically, the present disclosure is directed to determining (e.g., estimating) a state-of-charge (SOC) of the battery via a hybrid algorithm approach, the hybrid algorithm approach including a voltage look-up algorithm, a Coulomb counting algorithm, and one or more transitions there between based on one or more battery characteristics (e.g., conditions) satisfying (e.g., meeting) one or more pre-defined transition criteria.

A battery (e.g., a lithium-ion battery) may include, among other features, electrodes (e.g., at least one anode and at least one cathode), a separator, an electrolyte, and an enclosure in which the electrodes, separator, and electrolyte are disposed. The battery may also include a battery management unit (BMU) having memory circuitry stored thereon and processing circuitry configured to execute the instructions to perform various functions. The BMU may be disposed inside the enclosure, on the enclosure, outside of the enclosure, or any combination thereof.

In general, the battery may be configured to power a load, such as an electronic device. In some embodiments, the electronic device includes an audio device, such as earbuds (e.g., wireless earbuds), configured to be wirelessly coupled to an additional electronic device, such as a mobile phone. In embodiments employing earbuds, for example, each earbud may include a dedicated battery. That is, a first battery may power a first earbud and a second battery may power a second earbud.

In accordance with the present disclosure, various circuitry, such as the above-described processing circuitry and memory circuitry of the BMU, is employed to determine a state-of-charge (SOC) of the battery (e.g., the first battery powering the first earbud) and transmit an indication of the SOC of the battery to the additional electronic device (e.g., the mobile device) for output to a display of the additional electronic device. In this way, a user can monitor the SOC of the battery of the electronic device (e.g., the earbud or earbuds) and determine if and when to charge the battery. For example, in embodiments including the earbuds, the user may dispose the earbuds in a charging case to charge the battery. In some embodiments, the charging case may include a power bank. Additionally or alternatively, the charging case may be coupled to a wall outlet.

In accordance with the present disclosure, the circuitry (e.g., of the BMU) may determine the SOC of the battery via a hybrid algorithm approach employing a voltage look-up algorithm, a Coulomb counting algorithm, and one or more transitions there between. For example, in certain first operating conditions (e.g., based on one or more first battery characteristics), only the voltage look-up algorithm is used for determining the SOC of the battery, in certain second operating conditions (e.g., based on one or more second battery characteristics), only the Coulomb counting algorithm is used for determining the SOC of the battery, and in certain third operating conditions (e.g., based on one or more third battery characteristics), both the voltage look-up algorithm and the Coulomb counting algorithm is used. For example, in the third operating conditions (e.g., based on the one or more third battery characteristics), the SOC of the battery is determined (e.g., estimated) by way of a weighted average between a first SOC estimate determined from the voltage look-up algorithm and a second SOC estimate determined by the Coulomb counting algorithm.

In the voltage look-up algorithm, also referred to as a gas gauge engine or a gas gauge algorithm, various pre-defined look-up tables (also referred to as pre-defined look-up curves) are employed to determine the SOC of the battery based on at least a temperature of the battery and a voltage of the battery (and, in certain instances, an electrical current of the battery). For example, the various pre-defined look-up tables (or pre-defined look-up curves) may correspond to various pre-defined temperatures of the battery, where a particular pre-defined look-up table is selected based on a detected temperature of the battery. A detected voltage may be employed to locate a point in the selected pre-defined look-up table (or on the pre-defined look-up curve), where the point indicates the SOC of the battery. In some embodiments, the detected electrical current of the battery is employed (e.g., along with the temperature) to select the pre-defined look-up table (or pre-defined look-up curve), is employed (e.g., along with the voltage) to locate the point in the pre-defined look-up table (or pre-defined look-up curve), or both. These and other aspects of the voltage look-up algorithm will be described in greater detail with reference to the drawings.

In the Coulomb counting algorithm, the circuitry (e.g., of the BMU) determines the SOC of the battery based on at least the electrical current of the battery. For example, in one embodiment, the electrical current flowing into and/or out of the battery is detected (e.g., measured) and integrated over time to calculate a total amount of charge that has entered the battery and/or left the battery, respectively. In this way, the SOC of the battery is determined based on an initial SOC plus the total amount of charge that has entered the battery and/or minus the total amount of charge that has left the battery. In certain embodiments, the Coulomb counting algorithm is only employed when the battery is in a discharging state (e.g., when charge is leaving the battery). The initial SOC employed by the Coulomb counting algorithm may be determined via the voltage look-up algorithm (e.g., prior to or during a transition from the voltage look-up algorithm to the Coulomb counting algorithm), for example, after determining that the initial SOC from the voltage look-up algorithm is reliable. These and other aspects of the Coulomb counting algorithm will be described in greater detail with reference to the drawings.

In certain instances of the present disclosure, reference is made to a filter of the hybrid algorithm approach and various states of the filter. For example, the filter may be in an engaged state, which means that the Coulomb counting algorithm alone is employed to determine the SOC, in a disengaged state, which means that the voltage look-up algorithm alone is employed to determine the SOC, and in an out transition state, which means that a weighted average between a first SOC estimate by the voltage look-up algorithm and a second SOC estimate by the Coulomb counting algorithm is employed to determine the SOC. As an example, the following equation may be used to determine the SOC in all filter states:

$${SOC}_{Weighted\_Average} = α * {SOC}_{Coloumb\_Counting} + ( 1 - ∝ ) * {SOC}_{Voltage\_Look - up} \qquad Equation l$$

With α set to 1, Equation 1 is reduced to the first term illustrated above and, thus, only the Coulomb counting algorithm is employed. In other words, with α set to 1, the filter is in the engaged state. With α set to 0, Equation 1 is reduced to the second term illustrated above and, thus, only the voltage look-up algorithm is employed. In other words, with α set to 0, the filter is in the disengaged state. With α set to any number between 0 and 1, exclusive, both the Coulomb counting algorithm and the voltage look-up algorithm are employed. In other words, with a set to any number between 0 and 1, exclusive, the filter is in the out transition state.

As described in greater detail with reference to later drawings, the processing circuitry (e.g., of the BMU) determines the state of the filter (e.g., the value of a in Equation 1 above) based on one or more operating conditions, such as one or more battery characteristics, also referred to as one or more battery conditions. In certain conditions, the filter may transition from the engaged state to the disengaged state. In other conditions, the filter may transition from the disengaged state to the engaged state. In still other conditions, the filter may transition from the engaged state to the out transition state. In still other conditions, the filter may transition from the out transition state to the disengaged state. The battery characteristics (e.g., conditions) for determining the state of the filter may include, but are not necessarily limited to, whether the battery is in a charging or discharging state, a voltage (or stability thereof) corresponding to the battery, a jump in the SOC of the battery over a period of time and/or between two adjacent samplings of the SOC, whether the SOC is above or below one or more threshold SOCs, whether the battery has reached an end of charge, and/or other possible battery characteristics (e.g., conditions).

In general, the battery characteristics and the corresponding states of the filter dependent on the battery characteristics, in accordance with the present disclosure, have been selected to improve an accuracy and/or reduce errors in determining the SOC. Indeed, in certain operating conditions, the voltage look-up algorithm is preferred for determining the SOC, while in certain other operating conditions, the Coulomb counting algorithm (e.g., engaging the filter) is preferred for determining the SOC. For example, it is presently recognized that the voltage look-up algorithm may be susceptible to errors when a state of the battery is changed from charging to discharging and/or discharging to charging, when voltage and/or temperature is unstable or otherwise in flux, etc. Additionally or alternatively, it is presently recognized that the Coulomb counting algorithm may be susceptible to errors, for example, if implemented over a relatively long period of time at least in part due to drift in a sensor configured to detect the electrical current of the battery. Additionally or alternatively, it is presently recognized that in certain conditions (e.g., based on certain battery characteristics), transitioning from the Coulomb counting algorithm (e.g., with the filter in the engaged state) to the voltage look-up algorithm (e.g., with the filter in the disengaged state) is best performed by employing a weighted average (e.g., with the filter in the out transition state) between the SOC estimate from the voltage look-up algorithm and the second SOC estimate from the Coulomb counting algorithm (e.g., until battery characteristics indicate that employing the voltage look-up algorithm alone, with the filter in the disengaged state, is suitable).

In general, presently disclosed systems and methods improve SOC accuracy and/or reduce SOC errors over traditional configurations without requiring undesirably large batteries and/or undesirably large discharge rates of batteries, thereby improving a user experience, improving operability of the load and the corresponding battery, etc. These and other aspects of the present disclosure are described in detail below with reference to the drawings.

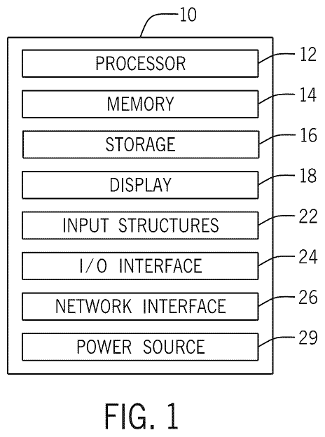

Continuing now with the drawings, FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer, a portable electronic or handheld electronic device such as a wireless electronic device or smartphone, a tablet, a wearable electronic device, and other similar devices. In additional or alternative embodiments, the electronic device 10 may include an access point, such as a base station, a router (e.g., a wireless or Wi-Fi router), a hub, a switch, and so on. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector, a universal serial bus (USB), or other similar connector and protocol. The network interface 26 may include, for example, one or more interfaces for a personal area network (PAN), such as an ultra-wideband (UWB) or a BLUETOOTH network, a local area network (LAN) or wireless local area network (WLAN), such as a network employing one of the IEEE 802.11x family of protocols (e.g., WI-FI), and/or a wide area network (WAN), such as any standards related to the Third Generation Partnership Project (3GPP), including, for example, a 3rd generation (3G) cellular network, universal mobile telecommunication system (UMTS), 4th generation (4G) cellular network, Long Term Evolution (LTE) cellular network, Long Term Evolution License Assisted Access (LTE-LAA) cellular network, 5th generation (5G) cellular network, and/or New Radio (NR) cellular network, a 6th generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX), mobile broadband Wireless networks (mobile WIMAX), asynchronous digital subscriber lines (e.g., ADSL, VDSL), digital video broadcasting-terrestrial (DVB-T) network and its extension DVB Handheld (DVB-H) network, ultra-wideband (UWB) network, alternating current (AC) power lines, and so forth.

The power source 29 of the electronic device 10 may include any suitable source of power, such as a rechargeable lithium polymer battery (e.g., a lithium-ion battery) and/or an alternating current (AC) power converter. In accordance with the present disclosure, the electronic device 10 may include an audio device (e.g., ear buds, such as wireless ear buds) or may be, for example, a smartphone communicatively coupled with an audio device (e.g., ear buds, such as wireless ear buds). For example, the electronic device 10 may be configured to determine a battery state-of-charge (SOC), or the electronic device 10 may be configured to display a battery SOC of a separate battery of a separate device (e.g., via a communicative coupling, such as a wireless communicative coupling, between the electronic device 10 and the separate device). Circuitry may be employed to determine the battery SOC via a hybrid algorithm approach that includes a voltage look-up algorithm, a Coulomb counting algorithm, and one or more transitions there between, where selection of the voltage look-up algorithm, the Coulomb counting algorithm, and/or the one or more transitions is based on one or more battery characteristics (e.g., conditions) satisfying (e.g., meeting) pre-defined transition criteria. These and other aspects of the present disclosure are described in detail below with reference to the drawings.

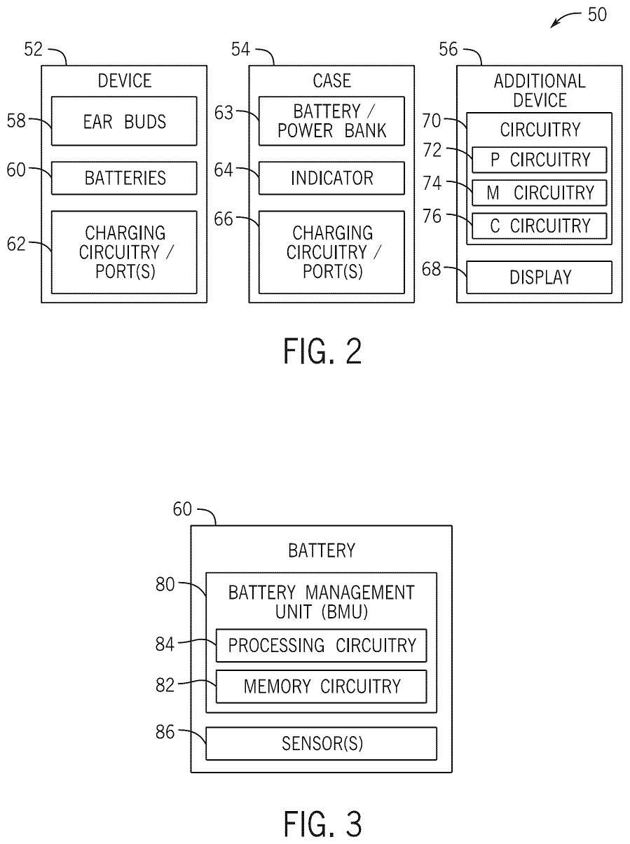

FIG. 2 is a schematic illustration of an embodiment of an electrical system 50 including a device 52 (e.g., an audio device, such as wireless earbuds), a case 54 for holding the device 52, and an additional device 56 (e.g., a mobile device, such as a smartphone, tablet, or laptop). In the illustrated embodiment, the device 52 includes ear buds 58, one or more batteries 60 (e.g., a first battery for a first ear bud of the ear buds 58 and a second battery for a second ear bud of the ear buds 58), and one or more charging mechanisms 62 (e.g., charging circuitry, charging ports or contacts, etc.). As shown, the case 54 may include a battery 63 (also referred to as a power bank), a charge indicator 64, and one or more charging mechanisms 66 (e.g., charging circuitry, charging ports or contacts, etc.). In general, the case 54 may be configured to charge the one or more batteries 60 of the device 52 (e.g., of the ear buds 58). For example, the case 54 may be coupled to a wall outlet to charge the battery 63 of the case 54, which in turn may be used to charge the one or more batteries 60 of the device 52 (e.g., of the ear buds 58). In some embodiments, an electrical coupling is established between the charging mechanism 66 of the case 54, such as electrical contacts of the case 54, and the one or more charging mechanisms 62 of the device 52, such as electrical contacts of the device 52. In this way, the battery 63 of the case 54 is configured charge the one or more batteries 60 of the device 52 (e.g., of the ear buds 58). However, other charging techniques are also possible in accordance with the present disclosure. The charge indicator 64 may be configured to indicate when the battery 63 of the case 54 is being charged (or is charged above a threshold amount) and/or when the one or more batteries 60 (e.g., of the ear buds 58 of the device 52) are being charged (or are charged above a threshold amount).

In some embodiments, the device 52 is configured to be communicatively coupled (e.g., wirelessly coupled) with the additional device 56. Further, the device 52 may be configured to determine a state-of-charge (SOC) of the one or more batteries 60 (e.g., via one or more battery management units, or BMUs, of the one or more batteries 60). Further still, the device 52 may be configured to transmit an indication of the SOC to the additional device 56 for output to a display 68 of the additional device 56. For example, the additional device 56 in the illustrated embodiment includes circuitry 70 (e.g., processing circuitry 72, memory circuitry 74, and communications circuitry 76, such as transceiver circuitry) configured to receive and output the indication of the SOC to the display 68 of the additional device 56. In this way, a user can monitor the SOC of the one or more batteries 60 of the device 52 (e.g., via the display 68 of the additional device 56) without necessarily having a display of the device 52 itself and/or the case 54 itself. In embodiments employing multiple instances of the batteries 60, such as certain embodiments where the device 52 includes two of the ear buds 58, the SOC output to the display 68 of the additional device 56 may be an average of two SOCs corresponding to two of the ear buds 58. Additionally or alternatively, the additional device 56 may output to the display 68 first and second SOCs corresponding to two of the ear buds 58.

In accordance with the present disclosure, circuitry is configured to determine the SOC of the one or more batteries 60 via a hybrid algorithm approach, where the hybrid algorithm approach includes a voltage look-up algorithm, a Coulomb counting algorithm, and one or more transitions there between. For example, FIG. 3 is a schematic illustration of an embodiment of the battery 60 employed in the device 52 of FIG. 2, where the battery 60 in FIG. 3 includes a battery management unit (BMU) 80 configured to determine the SOC of the battery 60. In other embodiments, different circuitry is configured to determine the SOC of the battery 60. As shown, the BMU 80 of the battery 60 in FIG. 3 includes memory circuitry 82 storing instructions thereon and processing circuitry 84 configured to execute the instructions to perform various functions, such as determining the SOC of the battery 60 via the hybrid algorithm approach. The battery 60 also includes one or more sensors 86 (e.g., a temperature or thermal sensor, an electrical current sensor, a voltage sensor, etc.) configured to detect parameters or characteristics of the battery 60 (e.g., a temperature of the battery, an electrical current of the battery, a voltage of the battery, etc.), where the detected parameters or characteristics of the battery 60 are employed by the BMU 80 to determine the SOC of the battery 60 via the hybrid algorithm approach, which includes a voltage look-up algorithm, a Coulomb counting algorithm, and transitions there between.

For example, the voltage look-up algorithm of the hybrid algorithm approach may employ at least a detected temperature and a detected voltage (and, in some embodiments, a detected electrical current) to determine the SOC of the battery 60. That is, the detected temperature may be employed to select a pre-defined look-up table (also referred to as a pre-defined look-up curve) from a plurality of pre-defined look-up tables, and the detected voltage may be employed to locate a point in the selected pre-defined look-up table (or on the selected pre-defined look-up curve), where the point indicates the SOC of the battery 60. In some embodiments, the detected electrical current is also employed to select the pre-defined look-up table (or pre-defined look-up curve), to locate the point in the selected pre-defined look-up table (or on the selected pre-defined look-up curve), or both.

The Coulomb counting algorithm of the hybrid algorithm approach may employ at least a detected electrical current to determine the SOC of the battery 60. For example, the Coulomb counting algorithm may integrate the detected electrical current over time to determine a total amount of charge entering and/or leaving the battery 60, and then add and/or subtract the total amount of charge entering and/or leaving the battery 60, respectively, from an initial SOC of the battery 60 to determine the current SOC of the battery 60. However, in certain embodiments, the Coulomb counting algorithm is only employed when the battery is in a discharging state (e.g., when charge is leaving the battery). In some embodiments, the initial SOC of the battery 60 employed in the Coulomb counting algorithm is determined by way of the voltage look-up algorithm, for example, after determining that said initial SOC is reliable (e.g., based on a present or past voltage stability metric, SOC stability metric, or both).

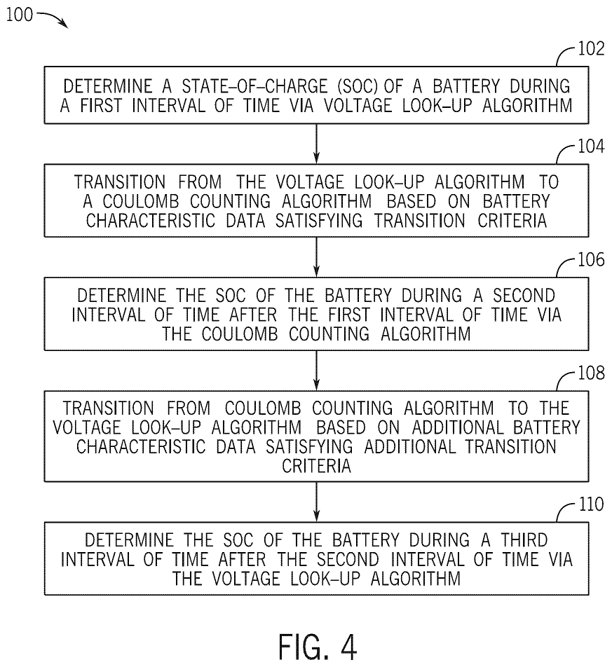

As an example of the hybrid algorithm approach, FIG. 4 is a high-level process flow diagram illustrating a method 100 of determining the SOC of the battery 60 of FIG. 3 via the hybrid algorithm, where the hybrid algorithm approach includes a voltage look-up algorithm, a Coulomb counting algorithm, and one or more transitions there between. While the method 100 may be performed in the order of the steps illustrated in FIG. 4 and described below, it should be understood that an order of the steps in certain embodiments of the method 100 may differ. Further, certain steps not illustrated in FIG. 4 and/or not described below may be employed in other embodiments of the method 100. Further still, certain steps illustrated in FIG. 4 and/or described below may be excluded in other embodiments of the method 100. The steps illustrated in FIG. 4 and described below are merely one embodiment of the method 100, but it should be understood that other embodiments of the method 100 in accordance with the present disclosure are also possible.

In the illustrated embodiment, the method 100 includes determining (block 102) a state-of-charge (SOC) of a battery during a first interval of time via a voltage look-up algorithm. For example, as previously described, sensors of the battery may determine at least a temperature of the battery and a voltage of the battery. The temperature of the battery may be employed to select a pre-defined look-up table (also referred to as a pre-defined look-up curve) from a variety of pre-defined look-up tables corresponding to a variety of pre-defined battery temperatures. The voltage of the battery may be employed to locate a point in the pre-defined look-up table (or on the pre-defined look-up curve), where the point indicates the SOC of the battery. In some embodiments, a detected electrical current of the battery is also employed for selecting the pre-defined look-up table (or pre-defined look-up curve), locating the point in the pre-defined look-up table (or on the pre-defined look-up curve), or both. In general, the pre-defined look-up tables (or pre-defined look-up curves) are determined via experimentation and stored to memory of the circuitry performing the method 100 (e.g., the BMU of the battery).

The method 100 also includes transitioning (block 104) from the voltage look-up algorithm to a Coulomb counting algorithm based on battery characteristic data satisfying transition criteria. Stated differently, the method 100 includes engaging a filter corresponding to the Coulomb counting algorithm based on the battery characteristic data satisfying transition criteria. As an example, transitioning from the voltage look-up algorithm to the Coulomb counting algorithm may be performed in response to one or more battery conditions being met (e.g., one or more battery characteristics meeting one or more pre-defined criteria), including: that the SOC is within a pre-defined range (e.g., between 20% and 99%, inclusive), above a pre-defined threshold (e.g., 20%), below a pre-defined threshold (e.g., 100%), or any combination thereof; that the battery is in a particular state, such as a discharging state; that voltage of the battery is stable or was stable at some point in time over a prior time range, such as the last 10 seconds, 15 seconds, or 30 seconds, in order to use the SOC determined by way of the voltage look-up algorithm as an initial SOC for use in the Coulomb counting algorithm; and/or other conditions. In some embodiments, all three of the conditions above must be met to perform the transition from the voltage look-up algorithm to the Coulomb counting algorithm (e.g., to engage the filter corresponding to the Coulomb counting algorithm).

The stability of the voltage of the battery may be determined, for example, by comparing a moving or rolling average of delta voltage (e.g., current voltage value minus last or most recent voltage) against an expected or threshold value, where exceeding the expected or threshold value indicates voltage instability, and not exceeding the expected or threshold value indicates stability. Whether the voltage is stable or instable may inform whether to transition from the Coulomb counting algorithm to the voltage look-up algorithm (e.g., disengaging the filter), from the voltage look-up algorithm to the Coulomb counting algorithm (e.g., engaging the filter), and/or employing the filter in the out transition state. Additionally or alternatively, voltage and/or SOC stability may be based on an extent of a jump (e.g., increase or decrease) in the SOC over a pre-defined period of time or other interval (e.g., between consecutive SOC determinations). For example, the voltage and/or SOC may be considered stable if the jump in the SOC is less than a threshold amount (e.g., the jump or delta in SOC is less than 2 percentage points) and unstable if the jump in the SOC is greater than a threshold amount or within a pre-defined range (e.g., the jump or delta in SOC is greater than 2 percentage points, within 2 percentage points and 50 percentage points, etc.). Further, other conditions considered for engaging the filter (e.g., for transitioning to the Coulomb counting algorithm) are also possible in accordance with the present disclosure.

The method 100 also includes determining (block 106) the SOC of the battery during a second interval of time after the first interval of time via the Coulomb counting algorithm. As previously described, the Coulomb counting algorithm may include integrating the detected electrical current of the battery over time to determine an amount of charge entering and/or leaving the battery. In certain embodiments, the filter is only engaged (e.g., the Coulomb counting algorithm is only used) when the battery is in a discharging state (e.g., when charge is leaving the battery). In any case, the amount of charge leaving the battery, for example, is deducted (e.g., subtracted) from an initial SOC determined by way of the voltage look-up algorithm. Because the Coulomb counting algorithm relies at least in part on the initial SOC determined by way of the voltage look-up algorithm, the Coulomb counting algorithm may only be initiated (e.g., the filter engaged) if the above-described condition that the voltage of the battery is stable or was stable at some point in time over the prior time range (e.g., 10 seconds, 15 seconds, or 30 seconds) is met (e.g., satisfied). That is, the Coulomb counting algorithm (e.g., the filter) may only be engaged when a reliable value for the initial SOC is available.

The method also includes transitioning (block 108) from the Coulomb counting algorithm to the voltage look-up algorithm based on additional battery characteristic data satisfying additional transition criteria. For example, transitioning from the Coulomb counting algorithm to the voltage look-up algorithm may be performed in response to one or more battery conditions being met, including: that the SOC is within a pre-defined range (e.g., between 1% and 20%, inclusive), above a pre-defined threshold (1%), below a pre-defined threshold (e.g., 20%), or any combination thereof; that the battery is in a particular state, such as a discharging state, or that the battery has reached end of charge; that the voltage and/or the SOC of the battery is stable (e.g., a jump in the SOC over two consecutive samplings or a pre-defined period of time is less than a threshold amount of percentage points); that the filter has been engaged (e.g., the Coulomb counting algorithm has been employed) for a threshold amount of time (e.g., 1 minute, 2 minutes, 3 minutes, or 5 minutes); and/or other conditions.

Depending on the embodiment, one or more of conditions above, two or more of conditions above, three or more of conditions above, four or more of conditions above, or all of conditions above are required to be met (e.g., satisfied) in order to transition from the Coulomb counting algorithm to the voltage look-up algorithm. Further, in certain embodiments or conditions, a hard transition from the Coulomb counting algorithm to the voltage look-up algorithm may be employed, while in other embodiments or conditions, a soft transition from the Coulomb counting algorithm to the voltage look-up algorithm (e.g., in which the filter is set to the out transition state first) may be employed. Whether to employ the hard transition or the soft transition may be based on which of the battery characteristics (e.g., conditions) meet (e.g., satisfy) pre-defined criteria (e.g., filter state criteria, transition criteria, etc.) in accordance with the present disclosure. Additional details regarding which of the condition(s) and/or which combination(s) of the condition(s) are required to transition at block 108 from the Coulomb counting algorithm to the voltage look-up algorithm will be described with respect to later drawings.

In some embodiments, as described above, transitioning from the Coulomb counting algorithm (e.g., with the filter in the engaged state) to the voltage look-up algorithm (e.g., with the filter in the disengaged state) at block 108 includes first moving the filter to the out transition state (e.g., prior to the disengaged state). With the filter in the out transition state, the SOC may correspond to a weighted average between a first SOC estimate from the voltage look-up algorithm and a second SOC estimate from the Coulomb counting algorithm. An example of the above-described states of the filter is readily apparent in the following equation, which may be used in all states of the filter to determine the SOC of the battery under the hybrid algorithm approach, and the corresponding description below:

$${SOC}_{Weighted\_Average} = α * {SOC}_{Coloumb\_Counting} + ( 1 - ∝ ) * {SOC}_{Voltage\_Look - up} \qquad Equation l$$

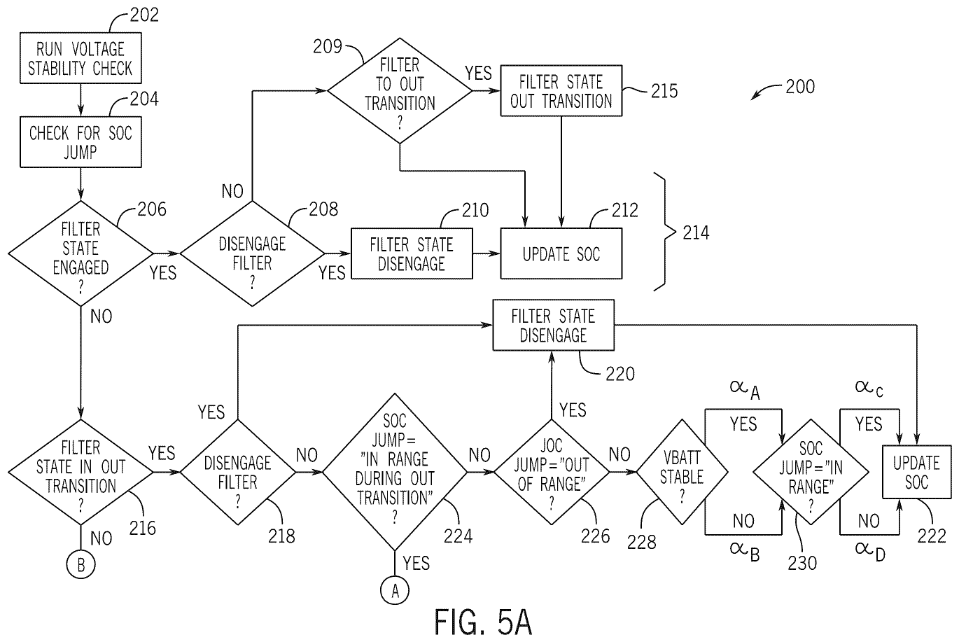

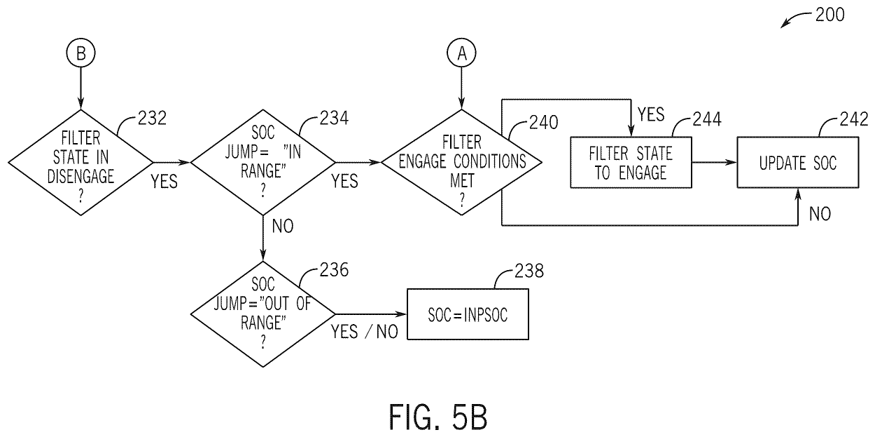

With a set to 1, Equation 1 is reduced to the first term illustrated above and, thus, only the Coulomb counting algorithm (also referred to as the Coulomb counting algorithm component) is employed. In other words, with a set to 1, the filter is in the engaged state. With a set to 0, Equation 1 is reduced to the second term illustrated above and, thus, only the voltage look-up algorithm (also referred to as the voltage look-up algorithm component) is employed. In other words, with a set to 0, the filter is in the disengaged state. With a set to any number between 0 and 1, exclusive, both the Coulomb counting algorithm and the voltage look-up algorithm are employed. In other words, with a set to any number between 0 and 1, exclusive, the filter is in the out transition state, and a weighted average (e.g., where a dictates the weights of the first and second terms) is employed to determine the SOC. It should be noted that a variety of values for a between 0 and 1, exclusive, may be employed with the filter in the out transition state. The value of a may depend on various characteristics of the battery, such as voltage stability and/or SOC stability, as described in greater detail with reference to later drawings, such as FIGS. 5A and 5B, below.

FIG. 5A and FIG. 5B are first and second portions, respectively, of an embodiment of a detailed process flow diagram illustrating hybrid algorithm logic 200 for determining a state-of-charge of the battery 60 of FIG. 3. The hybrid algorithm logic 200 illustrated in FIGS. 5A and 5B may correspond to logic (e.g., hardware logic, software logic, or both) employed in or by circuitry, such as the BMU 80 of the battery 60 in FIG. 3. It should be noted that the hybrid algorithm logic 200 in FIGS. 5A and 5B is merely one example implementation of the hybrid algorithm approach of the present disclosure, and that other implementations and/or embodiments are also possible.

In the illustrated embodiment, the hybrid algorithm logic 200 includes initiating (block 202) or running a voltage stability check and checking (block 204) for a jump in the SOC of the battery, as previously described. For example, a moving or rolling average of delta voltage (e.g., current voltage value minus last or most recent voltage value) is compared against an expected or threshold value to determine whether the voltage is stable at block 202. The voltage being stable or instable, as determined at block 202, informs later steps in the hybrid algorithm logic 200. Further, the jump in the SOC (e.g., between two adjacent samplings of the SOC), determined at block 204, is considered to be “in range” if it is between a pre-defined range (e.g., 2 percentage points and 50 percentage points) corresponding to filter state and/or transition criteria. In some embodiments, the jump in the SOC is considered “in range during out transition phase” based on different criteria, such as whether the jump in the SOC (e.g., in consecutive samplings or readings), as determined by the voltage look-up algorithm with the filter in the out transition state, is greater than 10% and less than 50%. If the SOC jump is neither “in range” nor “in range during out transition phase,” the SOC jump may be considered “out of range.” Whether the jump in the SOC is “in range,” “in range during out transition phase,” or “out of range,” as determined at block 204, informs later steps in the hybrid algorithm logic 200. In some embodiments, blocks 202 and/or 204 may be performed periodically (e.g., every 1 second, every 2 seconds, every 5 seconds, etc.) and the output(s) from blocks 202 and/or 204 may be employed to inform later aspects (e.g., decisions) of the hybrid algorithm logic 200.

The hybrid algorithm logic 200 also includes determining (block 206) whether the filter is in the engaged state described above with respect to earlier drawings. If the filter is in the engaged state, the hybrid algorithm logic 200 includes determining (block 208) whether to disengage the filter (e.g., directly from the engaged state without employing the filter out transition state therebetween). If the hybrid algorithm logic 200 determines that the filter should not be directly disengaged, the hybrid algorithm logic 200 proceeds to block 209 (described in greater detail below). If the hybrid algorithm logic 200 determines that the filter should be directly disengaged, the hybrid algorithm logic 200 disengages (block 210) the filter and then updates (block 212) the SOC of the battery (e.g., with the filter disengaged, or in other words, by only the voltage look-up algorithm). The filter may be directly disengaged (e.g., at block 210) from the engaged state based on one or more battery characteristics meeting certain transition criteria, such as the battery being in a fully charged state, the SOC is less than 20% and the battery is in a discharging state, or some other battery characteristic. Certain portions of block 208 are illustrated in, and described in greater detail with respect to, FIG. 8.

If at block 208 the hybrid algorithm logic 200 determines that the filter should not be directly disengaged from the engaged state, the hybrid algorithm logic 200 proceeds with determining (block 209) whether to move the filter to the out transition state. Moving the filter to the out transition state may be based on a determination that the filter has been engaged for more than a threshold amount of time (e.g., 1 minute, 2 minutes, 3 minutes, 5 minutes, etc.), among other possible battery characteristics (e.g., described with respect to earlier embodiments and/or the embodiment illustrated in FIG. 7). If the hybrid algorithm logic 200 determines at block 209 that the filter should not be moved to the out transition state, the SOC of the battery is updated at block 212 with the filter engaged (e.g., via the Coulomb counting algorithm only). If the hybrid algorithm logic 200 determines at block 209 that the filter should not be moved to the out transition state, the filter is moved to the out transition state at block 215 and then the SOC of the battery is updated with the filter in the out transition state (e.g., based on a weighted average of a first SOC estimate from the voltage look-up algorithm and a second SOC estimate from the Coulomb counting algorithm).

In general, whether to maintain the filter in the engaged state, move the filter to the disengaged state, or move the filter to the out transition state is based on various battery characteristics described in the present disclosure to maintain an accuracy and/or reliability of the SOC. For example, as previously described, the voltage look-up algorithm may become less accurate and/or reliable in various unstable battery conditions (e.g., when voltage is unstable, temperature is unstable, etc.), and the Coulomb counting algorithm may become less accurate and/or reliable if employed over an undesirable long period of time (e.g., due to sensor drift in the current sensor). Blocks 206 through 212 may represent a branch 214 of the hybrid algorithm logic 200 in which the filter state is hard transitioned from the engaged state to the disengaged state, without employing the out transition state, in order to ensure, as previously described, the accuracy and/or reliability of the SOC displayed to the user and/or employed by the battery or the load to perform various operations.

If at block 206 the hybrid algorithm logic 200 determines that the filter corresponding to the Coulomb counting algorithm is not in the engaged state, the hybrid algorithm logic 200 determines (block 216) whether the filter is in the out transition state. That is, the hybrid algorithm logic 200 determines whether the approach is in the process of transitioning from the Coulomb counting algorithm to the voltage look-up algorithm. If the hybrid algorithm logic 200 determines that the filter state is in the out transition at block 216, the hybrid algorithm logic 200 may determine (block 218) whether to disengage the filter. For example, as previously described, this decision may be based on one or more battery characteristics, such as based on the voltage stability check at block 202, the check for the jump in the SOC at block 204, and/or other battery characteristics. With the filter being in the disengaged state at block 220, the SOC is then updated at block 222, for example, via the voltage look-up algorithm (e.g., based on the second term in Equation 1 described with respect to FIG. 4, or by setting α to 0).

If at block 218 the hybrid algorithm logic 200 determines that the filter will not or should not be disengaged, the hybrid algorithm logic 200 then determines (block 224) whether the jump in the SOC, as determined at block 204, is “in range during out transition phase,” as previously described. If it not, the hybrid algorithm logic 200 then determines (block 226) whether the jump in the SOC, as determined at block 204, is “out of range,” as previously described. If it is, the filter is disengaged at block 220, described above. If it is not, the hybrid algorithm logic 200 proceeds to determine a value of a in Equation 1, where the value is between 0 and 1, exclusive. For example, the value of a may be based on a determination (block 228) of whether the voltage is stable (e.g., α_{A}) or is not stable (e.g., α_{B}) and an additional determination (block 230) of whether the SOC is “in range” (e.g., α_{C}) or not (e.g., α_{D}). In this way, a may be equal to a plus α_{C}, α_{A} plus α_{D}, α_{B} plus α_{C}, or α_{B} plus α_{D}. The SOC is then updated at block 222 employing Equation 1 and the value of a as determined above.

If at block 224 the hybrid algorithm logic 200 determines that the SOC jump (e.g., as determined at block 204) is “in range during out transition,” the hybrid algorithm logic 200 continues to Point A in FIG. 5B. Further, if at block 216 the hybrid algorithm logic 200 determines that the filter is in the out transition state, the hybrid algorithm logic 200 continues to Point B in FIG. 5B. Continuing from Point B in FIG. 5B, the hybrid algorithm logic 200 determines (block 232) whether the filter is in the disengaged state. Because the hybrid algorithm logic 200 already determined that the filter is in neither the engaged state nor the out transition state, the hybrid algorithm logic 200 may, in certain embodiments, necessarily determine that the filter is in the disengaged state at block 230 (e.g., since the three states of the filter include the engaged state, the out transition state, and the disengaged state). The hybrid algorithm logic 200 then determines (block 234) whether the jump in the SOC, as determined at block 204 in FIG. 5A, is “in range.” If it is not, then the hybrid algorithm logic 200 determines (block 236) whether the jump in the SOC is “out of range,” although in certain embodiments, the subsequent step is the same regardless of the outcome of block 236. For example, the hybrid algorithm logic 200 then updates (block 238) the SOC to be equal to the initial SOC (e.g., unchanged and/or as determined by the voltage look-up algorithm).

If at block 234 the hybrid algorithm logic 200 determines that the jump in the SOC is “in range,” the hybrid algorithm logic 200 determines (block 240) whether filter engage conditions are met. Block 240 may also be employed from Point A previously described with respect to FIG. 5A. If the filter engage conditions are not met, as determined at block 240, the SOC is updated (block 242) with the filter state disengaged or, in other words, via the voltage look-up algorithm (e.g., with a set to 0). If at block 240 the hybrid algorithm logic 200 determines that the filter engage conditions are met, the filter is engaged at block 244 and the SOC is then updated at block 242 with the filter state engaged or, in other words, via the Coulomb counting algorithm (e.g., with a set to 1). Additional details regarding the various filter states and conditions (e.g., battery characteristics) associated with the various filter states are described below with reference to later drawings.

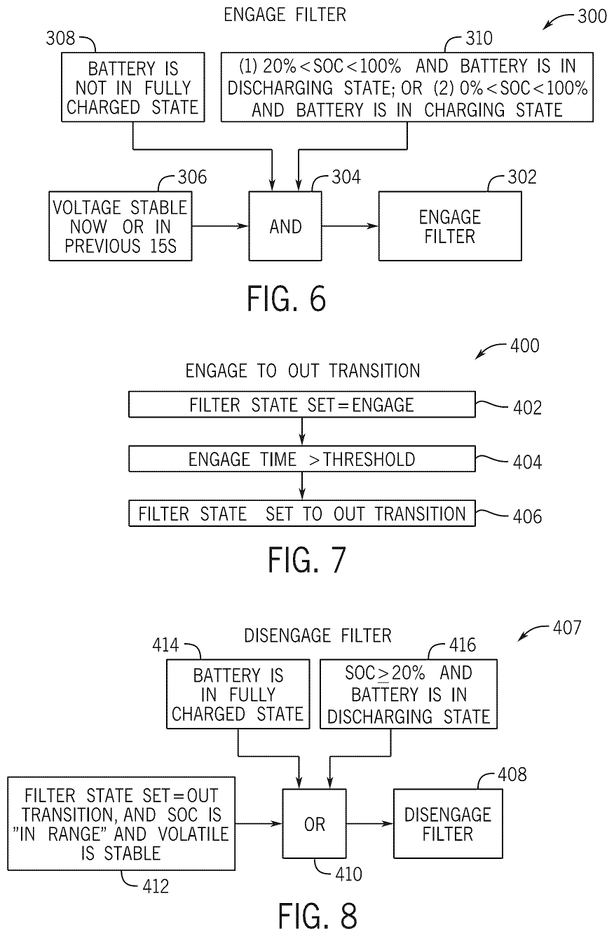

FIG. 6 is a process flow diagram illustrating an embodiment of a filter engage implementation 300 of the hybrid algorithm approach for determining the SOC of the battery. For example, the filter engage implementation 300 of FIG. 6 may be employed at block 240 of hybrid algorithm logic 200 in FIG. 5B. In the illustrated embodiment, the filter is set to the engaged state at block 302 in response to an “and” operation at block 304, in which various filter state and/or transition criteria are considered (e.g., with respect to various battery characteristics). For example, transitioning the filter to the engaged state at block 302 (e.g., from the disengaged state) may require determining, at block 304, that: the voltage of the battery is stable now or was stable in a prior time range (e.g., the last 10 seconds, 15 seconds, or 30 seconds), as represented by block 306 (or, in other embodiments, a similar determination that the SOC is or was stable); the battery is not in a fully charged state, as represented by block 308; and that either (1) the SOC of the battery is between 20% and 100% and the battery is in a discharging state or (2) the SOC of the battery is between 0% and 100% and the battery is in a charging state, as represented by block 310. It should be noted that FIG. 6 is merely an example of various battery characteristics that may be considered when determining whether to set the filter to the engaged state, and that other examples are also possible in accordance with the present disclosure.

FIG. 7 is a process flow diagram illustrating an embodiment of a filter out transition implementation 400 of a hybrid algorithm approach for determining the SOC of the battery. For example, the filter out transition implementation 400 may be employed via at least block 215 in the hybrid algorithm logic 200 of FIG. 5A. In FIG. 7, if the current state of the filter is engaged, as represented by block 402, and the filter has been engaged for more than a pre-defined threshold amount of time (e.g., 1 minute, 2 minutes, 3 minutes, or 5 minutes), as represented by block 404, then the filter may be set to the out transition state, as represented by block 406.

FIG. 8 is a process flow diagram illustrating an embodiment of a filter disengage implementation 407 of a hybrid algorithm approach for determining a state-of-charge of the battery. For example, the filter is set to the disengaged state at block 408 in response to an “or” operation at block 410, in which various filter state and/or transition criteria are considered (e.g., with respect to various battery characteristics). For example, the filter is set to the disengaged state at block 408 if one or more battery characteristics are met (e.g., satisfied) at block 410. These battery characteristics may include, for example, if the filter is in the out transition state and various transition criteria is met (e.g., SOC is “in range” and voltage is stable), as represented by block 412; if the battery is in a fully charged state, as represented by block 414; or if the SOC of the battery is less than or equal to 20% and the battery is in a discharging state, as represented by block 416.

Technical benefits of presently disclosed techniques include improved accuracy in determining an SOC of a battery, improved user experience, reduced size and power draw relative to traditional configurations employing one or more ASICs, or any combination thereof.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112 (f). However, for any claims containing elements designated in any other manner, it is intended that such elements are not to be interpreted under 35 U.S.C. 112 (f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. One or more tangible, non-transitory, computer-readable media storing instructions thereon that, when executed by processing circuitry, are configured to cause the processing circuitry to:
determine a state-of-charge (SOC) of a battery during a first interval of time via a voltage look-up algorithm;
transition from the voltage look-up algorithm to a Coulomb counting algorithm based on battery characteristic data satisfying transition criteria; and
determine the SOC of the battery during a second interval of time after the first interval of time via the Coulomb counting algorithm.

2. The one or more tangible, non-transitory, computer-readable media of claim 1, wherein the instructions, when executed by the processing circuitry, are configured to cause the processing circuitry to determine, during a third interval of time different than the first interval of time and the second interval of time, the SOC of the battery as a weighted average of a first SOC estimate from the voltage look-up algorithm and a second SOC estimate from the Coulomb counting algorithm.

3. The one or more tangible, non-transitory, computer-readable media of claim 1, wherein the transition criteria comprises one or both of a voltage stability threshold or an SOC threshold.

4. The one or more tangible, non-transitory, computer-readable media of claim 1, wherein the instructions, when executed by the processing circuitry, are configured to cause the processing circuitry to transition from the Coulomb counting algorithm to the voltage look-up algorithm based on additional battery characteristic data satisfying additional transition criteria.

5. The one or more tangible, non-transitory, computer-readable media of claim 4, wherein the transition criteria is different than the additional transition criteria.

6. The one or more tangible, non-transitory, computer-readable media of claim 4, wherein the instructions, when executed by the processing circuitry, are configured to cause the processing circuitry to determine the SOC of the battery during a third interval of time after the second interval of time via the voltage look-up algorithm.

7. The one or more tangible, non-transitory, computer-readable media of claim 1, wherein the instructions, when executed by the processing circuitry, are configured to cause the processing circuitry to:
determine the SOC of the battery during the first interval of time via the voltage look-up algorithm based at least in part on a temperature of the battery; and
determine the SOC of the battery during the second interval of time via the Coulomb counting algorithm based at least in part on a current of the battery.

8. The one or more tangible, non-transitory, computer-readable media of claim 1, wherein the instructions, when executed by the processing circuitry, are configured to cause the processing circuitry to transmit indications of the SOC to a mobile device.

9. A battery comprising a battery management unit (BMU), wherein the BMU is configured to:
determine a state-of-charge (SOC) of the battery during a first interval of time via a voltage look-up algorithm;
transition from the voltage look-up algorithm to a Coulomb counting algorithm based on battery characteristic data satisfying transition criteria; and
determine the SOC of the battery during a second interval of time after the first interval of time via the Coulomb counting algorithm.

10. The battery of claim 9, comprising a sensor configured to detect a parameter of the battery, wherein the BMU is configured to:
receive sensor feedback from the sensor indicative of the parameter; and
determine the SOC of the battery during the first interval of time via the voltage look-up algorithm based at least in part on the sensor feedback.

11. The battery of claim 10, wherein the sensor is a temperature or thermal sensor and the parameter is a temperature.

12. The battery of claim 9, comprising a sensor configured to detect a parameter of the battery, wherein the BMU is configured to:
receive sensor feedback from the sensor indicative of the parameter; and
determine the SOC of the battery during the second interval of time via the Coulomb counting algorithm based at least in part on the sensor feedback.

13. The battery of claim 12, wherein the sensor is a current sensor and the parameter is a current.

14. The battery of claim 9, wherein the transition criteria comprises a voltage stability threshold, an SOC threshold, or both.

15. The battery of claim 9, wherein the BMU is configured to transition from the Coulomb counting algorithm to the voltage look-up algorithm based on additional battery characteristic data satisfying additional transition criteria.

16. A method comprising:
determining a state-of-charge (SOC) of a battery via a hybrid algorithm comprising a voltage look-up algorithm component and a Coulomb counting algorithm component;
transitioning from the voltage look-up algorithm component to the Coulomb counting algorithm component based on battery characteristic data satisfying transition criteria; and
transitioning from the Coulomb counting algorithm component to the voltage look-up algorithm component based on additional battery characteristic data satisfying additional transition criteria.

17. The method of claim 16, wherein:
the transition criteria comprises a voltage stability threshold, an SOC threshold, or both; and
the additional transition criteria comprises an additional voltage stability threshold, an additional SOC threshold, or both.

18. The method of claim 16, comprising:
determining a first instance of the SOC of the battery during a first interval of time based on the voltage look-up algorithm component of the hybrid algorithm; and
determining a second instance of the SOC of the battery during a second interval of time different than the first interval of time based on the Coulomb counting algorithm component of the hybrid algorithm.

19. The method of claim 18, comprising:
determining a temperature of the battery during the first interval of time as an input to the voltage look-up algorithm component; and
determining a current of the battery during the second interval of time as an additional input to the Coulomb counting algorithm component.

20. The method of claim 17, comprising transmitting indications of the SOC to a mobile device.
